(19) United States
(12) Patent Application Publication
(10) Pub. No.: US 2018/0135161 A1
(43) Pub. Date: May 17, 2018

(54) FILM FORMATION APPARATUS AND FILM FORMATION METHOD

(71) Applicant: TOKYO ELECTRON LIMITED, Tokyo (JP)

(72) Inventors: Madoka FUJIMOTO, Koshi-shi (JP); Takashi FUSE, Nirasaki-shi (JP)

(21) Appl. No.: 15/869,800

(22) Filed: Jan. 12, 2018

Related U.S. Application Data
(63) Continuation of application No. PCT/JP2016/081183, filed on Oct. 20, 2016.

(30) Foreign Application Priority Data
Oct. 22, 2015 (JP) 2015-208417

(51) Int. Cl. C23C 14/12; C23C 14/50

(52) U.S. Cl. CPC C23C 14/12; C23C 14/50

(57) ABSTRACT

A film formation apparatus for forming a self-assembled monomolecular film on a film formation surface of a substrate includes: a chamber for accommodating the substrate, the chamber including a facing inner wall surface facing the film formation surface of the substrate, the facing inner wall surface being a ground potential surface; a source gas supply part for supplying a source gas for the self-assembled monomolecular film into the chamber; and an electrode positioned between the film formation surface of the substrate accommodated in the chamber and the facing inner wall surface of the chamber, and configured to form an electric field in a direction extending from the film formation surface of the substrate accommodated in the chamber toward the facing inner wall surface of the chamber or in a direction extending from the facing inner wall surface of the chamber toward the film formation surface of the substrate.

This application is a bypass continuation application of international application No. PCT/JP2016/081183 having an international filing date of Oct. 20, 2016 and designating the United States, the international application being based upon and claiming the benefit of priority from Japanese Patent Application No. 2015-208417, filed on Oct. 22, 2015, the entire contents of which are incorporated herein by reference.

### TECHNICAL FIELD

The present disclosure relates to a film formation apparatus and a film formation method for forming a self-assembled monomolecular film on a film formation surface of a substrate. Furthermore, the present disclosure relates to a storage medium which stores a program for executing the film formation method of the present disclosure.

### BACKGROUND

In recent years, organic thin films made of an organic compound have been used in various fields. For example, in the field of organic semiconductors such as organic transistors or the like, organic semiconductor films made of an organic compound are used.

As an organic thin film composed of such an organic compound, a self-assembled monomolecular (SAM) film which is formed in a self-assembled manner and has high orderliness has been used.

The self-assembled monomolecular film refers to a monomolecular film which is obtained by forming a chemical bond on a surface of a predetermined substrate through the use of organic compounds having a functional group forming a predetermined chemical bond as a terminal group and arranging anchored organic compounds in an ordered manner by the regulation from the surface of the substrate and the interaction between the organic compounds.

Such a self-assembled monomolecular film is effective not only as an organic semiconductor film itself but also for modifying a surface of a material. For example, it is considered that the self-assembled monomolecular film is used for an application in which the electric characteristics of an organic transistor are improved by modifying substrate surface characteristics (e.g., wettability, lipophilicity, etc.) of the organic transistor.

In the related art, a self-assembled monomolecular film using a silane coupling agent is formed on a SiO₂-based substrate to modify a surface of the substrate. The self-assembled monomolecular film using a silane coupling agent has an organic functional group such as an alkyl group, a fluorinated alkyl group or the like and can impart water repellency to the surface of the substrate.

In addition, as a method of forming a self-assembled monomolecular film using a silane coupling agent, there is known a method of exposing a substrate to a vapor of a silane coupling agent, a method of immersing a substrate in a silane coupling agent solution and a method of coating a silane coupling agent on a substrate, and the like.

On the other hand, there is known a method of forming a self-assembled monomolecular film by hydrogen-terminating a surface of a polysilicon layer, supplying an organic compound having a carbon double bond at a terminal to the hydrogen-terminated surface, and causing the organic compound to react with Si.

### SUMMARY

The present disclosure provides some embodiments of a film formation apparatus and a film formation method capable of forming a high-density self-assembled monomolecular film, and a storage medium storing a program for executing the film formation method.

According to one embodiment of the present disclosure, there is provided a film formation apparatus for forming a self-assembled monomolecular film on a film formation surface of a substrate, including: a chamber configured to accommodate the substrate and including a facing inner wall surface facing the film formation surface of the substrate accommodated in the chamber, the facing inner wall surface being a ground potential surface; a source gas supply part configured to supply a source gas for the self-assembled monomolecular film into the chamber; and an electrode positioned between the film formation surface of the substrate accommodated in the chamber and the facing inner wall surface of the chamber, and configured to form an electric field in a direction extending from the film formation surface of the substrate accommodated in the chamber toward the facing inner wall surface of the chamber or in a direction extending from the facing inner wall surface of the chamber toward the film formation surface of the substrate accommodated in the chamber.

According to another embodiment of the present disclosure, there is provided a film formation method for forming a self-assembled monomolecular film on a film formation surface of a substrate, including: accommodating the substrate in a chamber having a ground potential surface as an inner wall surface so that at least a portion of the ground potential surface becomes a facing inner wall surface facing the film formation surface of the substrate; and supplying a source gas for the self-assembled monomolecular film into the chamber, wherein the supplying a source gas includes forming an electric field using an electrode positioned between the film formation surface of the substrate accommodated in the chamber and the facing inner wall surface of the chamber, in a direction extending from the film formation surface of the substrate accommodated in the chamber toward the facing inner wall surface of the chamber or in a direction extending from the facing inner wall surface of the chamber toward the film formation surface of the substrate accommodated in the chamber.

According to another embodiment of the present disclosure, there is provided a non-transitory computer-readable storage medium storing a program that, when executed by a computer for controlling an operation of a film formation apparatus, causes the computer to control the film formation apparatus so as to perform the aforementioned film formation method.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram showing a configuration of a film formation apparatus according to one embodiment of the present disclosure.

FIG. 2 is a partial sectional view showing a configuration of a film forming unit included in the film formation apparatus shown in FIG. 1.

FIG. 3 is a plan view of a substrate held by a substrate holding part included in the film forming unit shown in FIG. 2, which is viewed in a plan view from a film formation surface side of a substrate.

FIG. 4 is a partial sectional view showing a modification of the substrate holding part included in the film forming unit shown in FIG. 2.

FIG. 5 is a plan view of a substrate held by the substrate holding part shown in FIG. 4, which is viewed in a plan view from the film formation surface side of a substrate.

FIG. 6 is a partial sectional view showing a configuration of a modification of the film forming unit shown in FIG. 2.

FIG. 7 is a plan view of an electrode included in the film forming unit shown in FIG. 6, which is viewed in a plan view from a bottom wall portion side of a chamber.

FIG. 8 is a diagram showing a relationship between a DC voltage applied to a frame portion and a contact angle of a self-assembled monomolecular film formed on a film formation surface of a substrate with respect to water.

### DETAILED DESCRIPTION

Embodiments of the present disclosure will now be described with reference to the accompanying drawings.

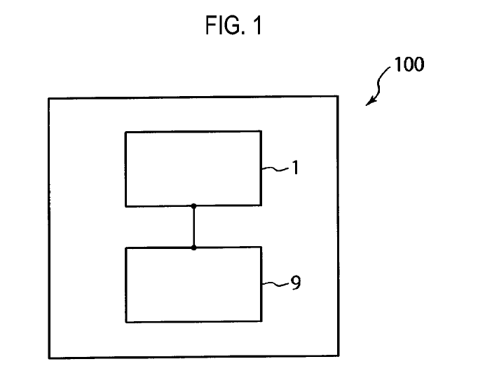

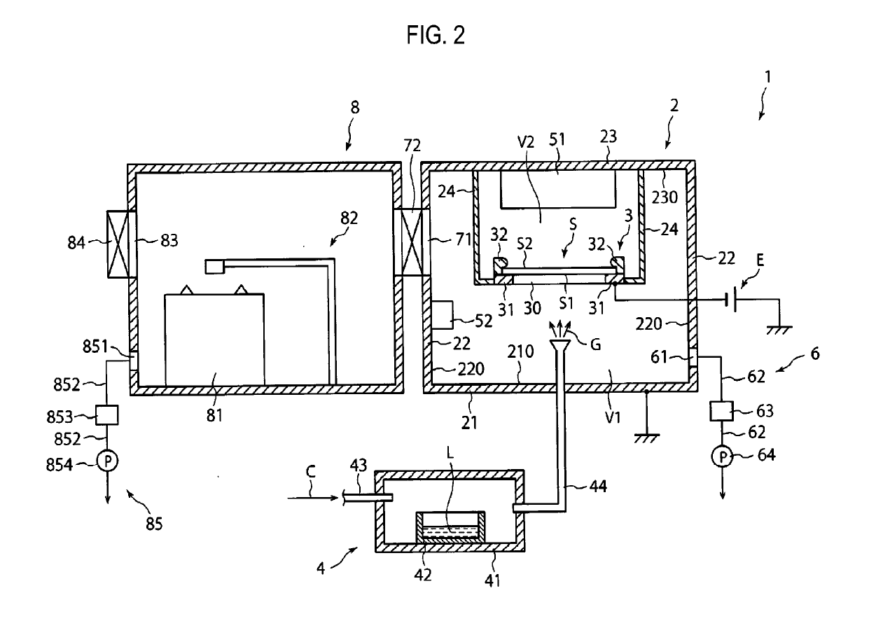

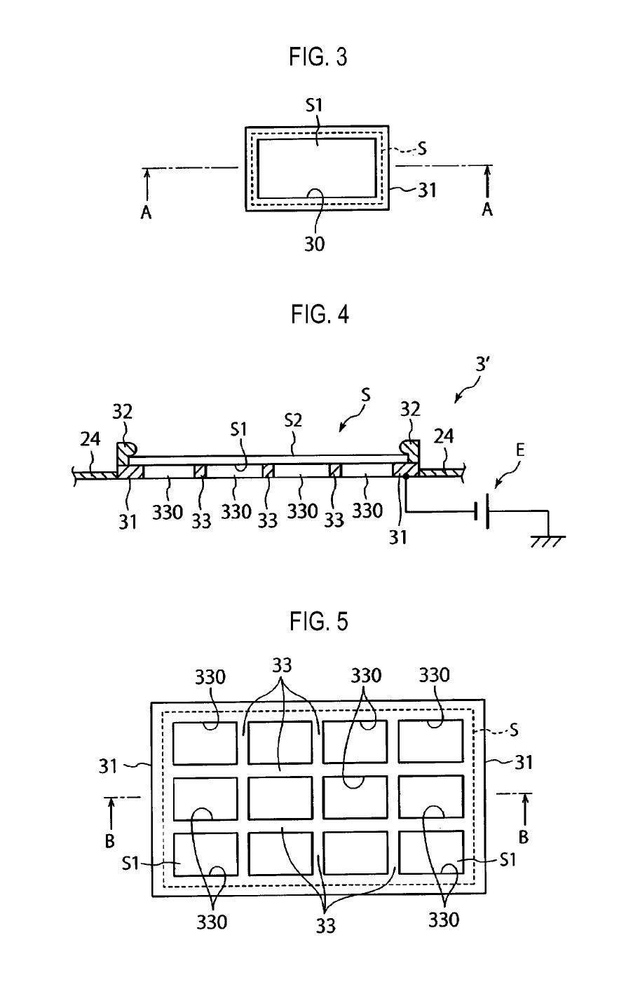

FIG. 1 is a schematic diagram showing a configuration of a film formation apparatus according to one embodiment of the present disclosure. FIG. 2 is a partial sectional view showing a configuration of a film forming unit included in the film formation apparatus shown in FIG. 1. FIG. 3 is a plan view of a substrate held by a substrate holding part included in the film forming unit shown in FIG. 2, which is viewed in a plan view from the film formation surface side of a substrate. The cross section of the substrate holding part in FIG. 2 corresponds to the cross section taken along line A-A in FIG. 3.

A film formation apparatus 100 according to the present embodiment is an apparatus for carrying out a film formation method for forming a self-assembled monomolecular film (hereinafter sometimes referred to as “SAM”) on a film formation surface of a substrate.

In the present embodiment, a substrate S having two surfaces is used as a substrate. Among the two surfaces of the substrate S, one surface is a film formation surface S1 on which a SAM is formed, and the other surface is a film non-formation surface S2 on which a SAM is not formed. A material constituting the substrate S is not particularly limited. Examples of the material constituting the substrate S may include an inorganic material such as SiO₂ (glass), Si, alumina, ceramics, sapphire or the like, and an organic material such as a plastic, a film or the like. The substrate S may be a substrate which has been subjected to a surface treatment such as a plasma treatment (plasma etching), a wet cleaning treatment, a film forming treatment or the like.

As shown in FIG. 1, the film formation apparatus 100 includes a film forming process unit 1 and a control part 9 that controls the operation of the film forming process unit 1.

As shown in FIG. 2, the film forming process unit 1 includes a chamber 2 configured to accommodate the substrate S, a substrate holding part 3 configured to hold the substrate S inside the chamber 2, a source gas supply part 4 configured to supply a source gas G for SAM into the chamber 2, a substrate heating part 51 configured to heat the substrate S held by the substrate holding part 3, an ultraviolet irradiation part 52 configured to irradiate ultraviolet rays to the source gas G for SAM supplied into the chamber 2, and an exhaust part 6 configured to discharge an internal atmosphere of the chamber 2.

As shown in FIG. 2, the chamber 2 has a bottom wall portion 21, a peripheral wall portion 22 standing from a peripheral edge portion of the bottom wall portion 21, and an upper wall portion 23 sealing an upper opening portion of the peripheral wall portion 22.

In the present embodiment, the bottom wall portion 21, the peripheral wall portion 22 and the upper wall portion 23 are formed of an electrically grounded electrical conductor. The entire inner wall surfaces of the chamber 2 (an inner wall surface 210 of the bottom wall portion 21, an inner wall surface 220 of the peripheral wall portion 22 and an inner wall surface 230 of the upper wall portion 23) are defined as ground potential surfaces whose potential is grounded. The electric conductor constituting the bottom wall portion 21, the peripheral wall portion 22 and the upper wall portion 23 is a metallic material made of, for example, a transition metal such as copper, nickel, titanium or the like, an alloy thereof, or a high-melting-point metal such as stainless steel, molybdenum, tungsten or the like.

As shown in FIG. 2, the substrate holding part 3 holds the substrate S inside the chamber 2 so that the inner wall surface 210 of the bottom wall portion 21, which is a portion of the ground potential surface of the chamber 2, becomes a facing inner wall surface facing the film formation surface S1 of the substrate S. Therefore, in the present embodiment, the inner wall surface 210 of the bottom wall portion 21 among the inner wall surfaces of the chamber 2 becomes a facing inner wall surface facing the film formation surface S1 of the substrate S held by the substrate holding part 3.

In the present embodiment, the bottom wall portion 21, the peripheral wall portion 22 and the upper wall portion 23 are formed of an electrically grounded electric conductor, and the entire inner wall surfaces of the chamber 2 become ground potential surfaces. However, among the inner wall surfaces of the chamber 2, at least the facing inner wall surface facing the film formation surface S1 of the substrate S held by the substrate holding part 3, namely the inner wall surface 210 of the bottom wall portion 21 may be a ground potential surface. The inner wall surface 220 of the peripheral wall portion 22 and the inner wall surface 230 of the upper wall portion 23 may not be ground potential surfaces. Therefore, the peripheral wall portion 22 and the upper wall portion 23 may be made of an insulator.

While in the present embodiment, the entire bottom wall portion 21 is made of an electrically grounded electrical conductor, at least the portion of the bottom wall portion 21 constituting the inner wall surface 210 may be composed of an electrically grounded electric conductor. Therefore, the bottom wall portion 21 may have an outer wall surface side portion made of an insulator and an inner wall surface side portion composed of an electrically grounded electrical conductor.

As shown in FIG. 2, the substrate holding part 3 includes a frame portion 31 and a chuck portion 32. As shown in FIGS. 2 and 3, the frame portion 31 has an opening portion 30 through which the film formation surface S1 of the substrate S is exposed toward the inner wall surface 210 of the bottom wall portion 21 of the chamber 2. The frame portion 31 supports a peripheral portion of the film formation surface S1 of the substrate S and exposes the film formation surface S1 of the substrate S toward the inner wall surface 210 of the bottom wall portion 21 of the chamber 2 through the opening portion 30. As shown in FIG. 3, the plane view shape of an outer peripheral line and an inner peripheral line of the frame portion 31 is a rectangular shape. However, the plane view shape of the outer peripheral line and the inner peripheral line of the frame portion 31 may be suitably changed to other shapes (for example, a circular shape or the like). The size of the opening portion 30 is, for example, 100 mm×50 mm. The chuck portion 32 is rotatable about the end portion on the side of the frame portion 31. When the substrate S is placed on the frame portion 31, the chuck portion 32 is rotated radially outward of the frame portion 31 and is located at a position (standby position) where the chuck portion 32 does not interfere with the substrate S placed on the frame portion 31. On the other hand, after the substrate S is placed on the frame portion 31, the chuck portion 32 is rotated radially inward of the frame portion 31 and is located at a position (holding position) where the chuck portion 32 holds the outer edge portion of the substrate S supported by the frame portion 31. Thus, the chuck portion 32 holds the outer edge portion of the substrate S supported by the frame portion 31.

The frame portion 31 is formed of an electric conductor and is electrically insulated from the ground potential surface of the chamber 2. The electric conductor constituting the frame portion 31 is a metallic material composed of a transition metal such as copper, nickel, titanium or the like, an alloy thereof, or a high-melting-point metal such as stainless steel, molybdenum, tungsten or the like. As shown in FIG. 2, a power source E for applying a negative DC voltage to the frame portion 31 is electrically connected to the frame portion 31. The power source E electrically connected to the frame portion 31 may be an internal power source included in the film formation apparatus 100 or an external power source. In the case where the external power source is electrically connected to the frame portion 31, the film formation apparatus 100 may include an external power source connection terminal electrically connected to the frame portion 31 so as to connect the external power source to the frame portion 31.

In the present embodiment, as the negative DC voltage is applied to the frame portion 31 by the power source E, the frame portion 31 functions as an electrode having a negative potential with respect to the ground potential surface. That is to say, the frame portion 31 is positioned between the film formation surface S1 of the substrate S held by the substrate holding part 3 and the inner wall surface 210 of the bottom wall portion 21 of the chamber 2. The frame portion 31 functions as an electrode for forming an electric field in a direction extending from the inner wall surface 210 of the bottom wall portion 21 of the chamber 2 toward the film formation surface S1 of the substrate S held by the substrate holding part 3. Since the substrate S is not interposed between the frame portion 31 and the inner wall surface 210 of the bottom wall portion 21 of the chamber 2, the electric field generated by the application of the voltage to the frame portion 31 is hardly affected by the dielectric constant of the substrate S. As a result, regardless of the material of the substrate S, an electric field having a desired intensity can be formed between the film formation surface S1 of the substrate S held by the substrate holding part 3 and the inner wall surface 210 of the bottom wall portion 21 of the chamber 2.

As shown in FIG. 2, the chamber 2 includes a partition wall portion 24 installed therein, which divides the internal space of the chamber 2 into a first space V1 where the film formation surface S1 of the substrate S held by the substrate holding part 3 is exposed and a second space V2 where the film non-formation surface S2 of the substrate S held by the substrate holding part 3 is exposed. The partition wall portion 24 extends from the frame portion 31 to the upper wall portion 23 of the upper wall portion 23 of the chamber 2. A loading/unloading port (not shown) through which the substrate S is loaded into and unloaded from the substrate holding part 3 is formed in the partition wall portion 24. The first space V1 and the second space V2 are in communication with each other through the loading/unloading port. When the substrate S is not held by the substrate holding part 3, the first space V1 and the second space V2 are in communication with each other through the opening portion 30 of the frame portion 31. However, if the substrate S is held by the substrate holding part 3, the opening portion 30 of the frame portion 31 is closed by the substrate S held by the substrate holding part 3. Chamber 2 includes a gas purging part (not shown) that purges a gas by supplying an inert gas such as a nitrogen gas or the like to the second space V2. When the source gas G is supplied to the first space V1, the inert gas is supplied to the second space V2 by the gas purging part. Therefore, the source gas G supplied to the first space V1 does not move from the first space V1 to the second space V2. Thus, the formation of a SAM on the film non-formation surface S2 of the substrate S held by the substrate holding part 3 is prevented.

The partition wall portion 24 may be formed of an insulator or an electric conductor. However, in the case where the partition wall portion 24 is formed of an electric conductor, it is preferable that a connection portion between the partition wall portion 24 and the frame portion 31 or a connection portion between the partition wall portion 24 and the upper wall portion 23 is formed of an insulator in order to ensure that the frame portion 31 is electrically insulated from the ground potential surface of the chamber 2.

As shown in FIG. 2, the source gas supply part 4 includes a gas generation container 41, an organic compound storage container 42 installed inside the gas generation container 41, a carrier gas introduction pipe 43 configured to introduce a carrier gas C into the gas generation container 41 therethrough, and a source gas supply pipe 44 configured to supply the source gas G for SAM generated inside the gas generation container 41 into the chamber 2 therethrough.

The organic compound storage container 42 stores an organic compound L capable of forming a SAM. In the present embodiment, the organic compound L is in a liquid state. In the gas generation container 41, the source gas G for SAM is generated by vaporization of the organic compound L. In the case where the vaporization of the organic compound L is insufficient or when the organic compound L is a solid at room temperature, a heater may be installed in the organic compound storage container 42.

The source gas G for SAM produced by the vaporization of the organic compound L is transferred by the carrier gas C introduced into the gas generation container 41 from the carrier gas introduction pipe 43 and is supplied into the chamber 2 via the source gas supply pipe 44. The source gas G is supplied between the film formation surface S1 of the substrate S held by the substrate holding part 3 and the inner wall surface 210 of the bottom wall portion 21 of the chamber 2, namely to the first space V1. The carrier gas C is, for example, an N₂ gas. A flow rate of the carrier gas C introduced into the gas generation container 41 from the carrier gas introduction pipe 43 is, for example, 50 sccm. The term “sccm” represents cc (cm³) per minute in a standard state (0 degrees C./1 atm).

As shown in FIG. 2, the source gas G is discharged toward the film formation surface S1 of the substrate S from the tip of the source gas supply pipe 44 extending into the chamber 2 through the bottom wall portion 21 of the chamber 2. That is to say, the source gas G is supplied in a direction extending from the inner wall surface 210 of the bottom wall portion 21 of the chamber 2 toward the film formation surface S1 of the substrate S held by the substrate holding part 3. This makes it easier for the organic compound L in the source gas G to adhere onto the film formation surface S1 of the substrate S held by the substrate holding part 3, thereby improving the formation efficiency of the SAM on the film formation surface S1 of the substrate S. The distance between the tip of the source gas supply pipe 44 and the film formation surface S1 of the substrate S held by the substrate holding part 3 is, for example, 50 to 1,000 mm.

The organic compound L used in the present embodiment is an organic compound that has a main chain portion, a first functional group bonded to one end of the main chain portion and a second functional group bonded to the other end of the main chain portion. The first functional group is polarized to δ+ and the second functional group is polarized to δ−.

The main chain portion is, for example, a carbon chain. The number of carbon atoms contained in the carbon chain is not particularly limited and may be appropriately adjusted. In some embodiments, the number of carbon atoms may be 6 to 100. The carbon chain may be a saturated carbon chain or a non-saturated carbon chain. In some embodiments, the carbon chain may be a saturated carbon chain. The carbon chain may contain a heteroatom such as an oxygen atom, a nitrogen atom or the like. The hydrogen atom on the carbon atom constituting the main chain portion may be substituted with a halogen atom such as a fluorine atom, a chlorine atom or the like, or a functional group such as an alkyl group, an ether group or the like.

The first functional group is a functional group capable of chemically bonding with the film formation surface S1 of the substrate S. The chemical bond is, for example, a covalent bond. The first functional group which is preferred when the substrate S is composed of an inorganic material (e.g., SiO₂ (glass) or the like) may include, for example, —Si(R)ₙ(X)₃-n and the like. R is an alkyl group such as a methyl group or the like, X is a hydrolysable group such as a chlorine atom, a methoxy group, an ethoxy group, a 2-methoxyethoxy group, an acetoxy group or the like, and n is an integer of 0 to 3. The first functional groups which is preferred when the substrate S is an organic material (e.g., an organic synthetic resin or the like) may include, for example, a vinyl group (—CH═CH₂), an amino group (—NH₂), a methacryl group (—OOC(CH₃)C═CH₂), an isocyanate group (—N═C═O), a mercapto group (—SH), a ureido group (—NHCONH₂), an epoxy group and the like.

The second functional group is a functional group capable of imparting desired characteristics to the film formation surface S1 of the substrate S. The second functional group preferred when water repellency, oil repellency, low friction or the like is imparted to the film formation surface S1 of the substrate S may include, for example, —CF₃, —(CF₂)ₙ—CF₃ (wherein n is an arbitrary integer, for example, an integer of 2 to 7), and the like.

In the case of imparting water repellency to the film formation surface S1 of the substrate S, for example, CH₂═CH—CH₂—O—CH₂—CF₂—CF₃ or the like may be used as the organic compound L capable of forming a SAM.

In the organic compound L, the whole molecule is electrically neutral. However, the first functional group is polarized to δ+ and the second functional group is polarized to δ−. The polarization of the organic compound L is caused by the electronegativity of the atoms constituting the organic compound L. Atoms (e.g., F, O, etc.) having a relatively high electronegativity are likely to be δ−. Atoms (e.g., C, H, etc.) having a relatively low electronegativity tend to be δ+. For example, when the first functional group is —CH═CH₂ and the second functional group is —CF₃ or —CF₂—CF₃, depending on the electronegativity of the atoms constituting the main chain portion, the first functional group is likely to be polarized to δ+, and the second functional group tends to be polarized to δ−. For example, when the organic compound L is CH₂═CH—CH₂—O—CH₂—CF₂—CF₃, —CH═CH₂ as the first functional group is polarized to δ+ and —CF₂—CF₃ as the second functional group is polarized to δ−.

The substrate heating part 51 is an example of a film formation promotion treatment part that performs a SAM formation promotion treatment on the film formation surface S1 of the substrate S held by the substrate holding part 3. The substrate heating part 51 heats the substrate S held by the substrate holding part 3, thereby promoting the formation of a SAM on the film formation surface S1. That is to say, the film formation promotion treatment performed by the substrate heating part 51 is a heating treatment.

The substrate heating part 51 includes a heater such as a resistance heater, a lamp heater (e.g., an LED lamp heater) or the like. In the present embodiment, the substrate heating part 51 is installed at the side of the film non-formation surface S2 of the substrate S held by the substrate holding part 3 (i.e., in the second space V2 where the film non-formation surface S2 of the substrate S is exposed). Therefore, the substrate heating part 51 heats the substrate S from the side of the film non-formation surface S2 of the substrate S. The heating temperature of the substrate heating part 51 is, for example, 30 to 400 degrees C.

The ultraviolet irradiation part 52 is an example of the film formation promotion treatment part that performs a SAM formation promotion treatment on the film formation surface S1 of the substrate S held by the substrate holding part 3. The ultraviolet irradiation part 52 activates the first functional group of the organic compound L in the source gas G by irradiating ultraviolet rays to the source gas G supplied into the chamber 2, thereby promoting the formation of a SAM on the film formation surface S1. That is to say, the film formation promotion treatment performed by the ultraviolet irradiation part 52 is an ultraviolet ray irradiation.

The ultraviolet irradiation part 52 includes a UV lamp for irradiating ultraviolet rays. In the present embodiment, the ultraviolet irradiation part 52 is installed at the side of the film formation surface S1 of the substrate S held by the substrate holding part 3 (i.e., in the first space V1 in which the film formation surface S1 of the substrate S is exposed). Therefore, the ultraviolet irradiation part 52 irradiates ultraviolet rays toward the source gas G supplied into the first space V1.

In the present embodiment, the substrate heating part 51 and the ultraviolet irradiation part 52 are installed inside the chamber 2 as film formation promotion treatment parts that perform a SAM formation promotion treatment on the film formation surface S1 of the substrate S held by the substrate holding part 3. However, one or both of the substrate heating part 51 and the ultraviolet irradiation part 52 may be omitted.

As shown in FIG. 2, the exhaust part 6 includes one or more exhaust ports 61 formed in the wall portion (the peripheral wall portion 22 in the present embodiment) of the chamber 2, a pressure regulation valve 63 connected to the exhaust ports 61 via an exhaust pipe 62, and a vacuum pump 64 connected to the pressure regulation valve 63 via the exhaust pipe 62. As the vacuum pump 64 sucks an internal atmosphere of the chamber 2 through the exhaust ports 61 and the exhaust pipe 62, the internal atmosphere of the chamber 2 is discharged so that an internal pressure of the chamber 2 is reduced.

As shown in FIG. 2, a loading/unloading port 71 through which the substrate S is loaded and unloaded is formed in the wall portion (the peripheral wall portion 22 in the present embodiment) of the chamber 2. The loading/unloading port 71 can be opened and closed by an airtight shutter 72 such as a gate valve or the like.

As shown in FIG. 2, the loading/unloading port 71 is connected to a load lock chamber 8 via the airtight shutter 72. As shown in FIG. 2, the load lock chamber 8 includes a substrate mounting table 81, a transfer arm 82, and an atmospheric-side loading/unloading port 83. The atmospheric-side loading/unloading port 83 can be opened and closed by an airtight shutter 84 such as a gate valve or the like. The substrate S existing outside the load lock chamber 8 is transferred into the load lock chamber 8 and mounted on the substrate mounting table 81 by a transfer arm (not shown) which transfers the substrate S inside the transfer space of the atmospheric environment outside the load lock chamber 8. The substrate S mounted on the substrate mounting table 81 is transferred into the chamber 2 and mounted on the substrate holding part 3 by the transfer arm 82. That is to say, the transfer arm 82 installed inside the load lock chamber 8 can access the substrate mounting table 81 in the load lock chamber 8 and the substrate holding part 3 in the chamber 2. Furthermore, as shown in FIG. 2, an exhaust part 85 for exhausting an internal atmosphere of the load lock chamber 8 therethrough is formed in the wall portion (the peripheral wall portion in the present embodiment) of the load lock chamber 8. As shown in FIG. 2, the exhaust part 85 includes one or more exhaust ports 851 formed in the wall portion (the peripheral wall portion in the present embodiment) of the load lock chamber 8, a pressure regulation valve 853 connected to the exhaust ports 851 via an exhaust pipe 852, and a vacuum pump 854 connected to the pressure regulation valve 853 via the exhaust pipe 852. As the vacuum pump 854 sucks the internal atmosphere of the load lock chamber 8 via the exhaust ports 851 and the exhaust pipe 852, the internal atmosphere of the load lock chamber 8 is discharged so that the interior of the load lock chamber 8 is depressurized. The atmospheric pressure in the load lock chamber 8 is reduced to substantially the same pressure as the atmospheric pressure in the chamber 2.

The control part 9 is configured by, for example, a computer including a CPU, an MPU, a RAM, a ROM and the like. A memory part such as a RAM, a ROM or the like stores a program for controlling various processes executed by the film formation apparatus 100. A main control part such as a CPU, an MPU or the like controls the operation of the film formation apparatus 100 by reading and executing the program stored in the memory part such as a RAM, a ROM or the like. The program may be recorded on a computer-readable storage medium or may be installed from the storage medium to the memory part of the control part 9. Examples of the computer-readable storage medium may include a hard disk (HD), a flexible disk (FD), a compact disk (CD), a magneto-optical disk (MO), a memory card, and the like. On the storage medium, there is recorded, for example, a program for causing the computer to control the film formation apparatus 100 to execute a film formation method to be described later when the program is executed by the computer for controlling the operation of the film formation apparatus 100.

Hereinafter, the film formation method performed by the film formation apparatus 100 will be described.

The film formation method performed by the film formation apparatus 100, includes: a process (a) of accommodating the substrate S in the chamber 2 having a ground potential surface as an inner wall surface so that at least a portion of the ground potential surface (the inner wall surface 210 of the bottom wall portion 21 of the chamber 2 in the present embodiment) becomes the facing inner wall surface facing the film formation surface S1 of the substrate S; and a process (b) of supplying the SAM source gas G into the chamber 2.

Hereinafter, the process (a) will be described.

The substrate S is, for example, a SiO₂ (glass) substrate, an organic synthetic resin substrate, or the like. The substrate S may be subjected to a pretreatment before the process (a). Examples of the pretreatment include a surface treatment of the substrate S by a plasma treatment (plasma etching), and the like.

The substrate S is transferred into the load lock chamber 8 by a transfer arm (not shown) which transfers the substrate S inside a transfer space of an atmospheric environment existing outside the load lock chamber 8. When the substrate S is loaded into the load lock chamber 8, the airtight shutter 84 of the atmospheric-side loading/unloading port 83 is opened in a state in which the airtight shutter 72 at the side of the chamber 2 is closed and the interior of the load lock chamber 8 is brought to an atmospheric atmosphere by a vent mechanism (not shown). In this state, a transfer arm (not shown) enters the load lock chamber 8 and mounts the substrate S on the substrate mounting table 81. Thereafter, the airtight shutter 84 is closed, and the vacuum pump 854 of the exhaust part 85 is operated so that the internal atmospheric pressure of the load lock chamber 8 is depressurized to become approximately the same as the internal atmospheric pressure of the chamber 2.

After the internal pressure of the load lock chamber 8 is reduced, the airtight shutter 72 connecting the load lock chamber 8 and the chamber 2 is opened. The transfer arm 82 installed in the load lock chamber 8 picks up the substrate S from the substrate mounting table 81, enters the chamber 2, and mounts the substrate S on the frame portion 31 of the substrate holding part 3. At this time, the substrate S is mounted on the frame portion 31 in a state where the film formation surface S1 faces the side of the opening portion 30 of the frame portion 31. The frame portion 31 supports the peripheral portion of the film formation surface S1 of the substrate S and exposes the film formation surface S1 of the substrate S toward the inner wall surface 210 of the bottom wall portion 21 of the chamber 2 (the facing inner wall surface facing the film formation surface S1) through the opening portion 30. When the substrate S is mounted on the frame portion 31, the chuck portion 32 is located at a position (standby position) where the chuck portion 32 does not interfere with the substrate S mounted on the frame portion 31. After the substrate S is mounted on the frame portion 31, the chuck portion 32 is located at a position (holding position) where the chuck portion 32 holds the outer edge portion of the substrate S supported by the frame portion 31. In this way, the substrate S is accommodated in the chamber 2 while being held by the substrate holding part 3, so that the inner wall surface 210 of the bottom wall portion 21, which is a portion of the ground potential surface of the chamber 2, becomes the facing inner wall surface facing the film formation surface S1 of the substrate S. After mounting the substrate S, the transfer arm 82 is withdrawn from the chamber 2. Thereafter, the airtight shutter 72 is closed. The internal atmospheric pressure of the chamber 2 is maintained at a reduced pressure of, for example, 10 to 10⁻⁹ Pa, specifically 10⁻³ to 10⁻⁶ Pa, by the exhaust part 6.

Hereinafter, the process (b) will be described.

The source gas G for SAM produced by the vaporization of the organic compound L accommodated in the organic compound storage container 42 is transported by the carrier gas C introduced into the gas generation container 41 and is supplied into the chamber 2 through the source gas supply pipe 44. The source gas G reaches the film formation surface S1 of the substrate S held by the substrate holding part 3 through the opening portion 30 of the frame portion 31. The source gas G is discharged toward the film formation surface S1 of the substrate S from the tip of the source gas supply pipe 44 extending into the chamber 2 through the bottom wall portion 21 of the chamber 2. That is to say, the source gas G is supplied in a direction extending from the inner wall surface 210 of the bottom wall portion 21 of the chamber 2 toward the film formation surface S1 of the substrate S held by the substrate holding part 3. This makes it easier for the organic compound L in the source gas G to adhere onto the film formation surface S1 of the substrate S held by the substrate holding part 3, thereby improving the formation efficiency of the SAM on the film formation surface S1 of the substrate S.

The source gas G is supplied between the film formation surface S1 of the substrate S held by the substrate holding part 3 and the inner wall surface 210 of the bottom wall portion 21 of the chamber 2, namely to the first space V1. In the first space V1 to which the source gas G is supplied, an electric field is formed in a direction extending from the inner wall surface 210 of the bottom wall portion 21 of the chamber 2 toward the film formation surface S1 of the substrate S held by the substrate holding part 3, as a negative DC voltage is applied to the frame portion 31 by the power source E. The electric field is formed throughout the time period from the start to the end of the supply of the source gas G to the first space V1. Therefore, the organic compound L in the source gas G supplied to the first space V1 is oriented along the electric field because it is electrically neutral as the whole molecule but is internally polarized. That is to say, the first functional group polarized to δ+ faces the side of the film formation surface S1 of the substrate S held by the substrate holding part 3, and the second functional group polarized to δ− faces the side of the inner wall surface 210 of the bottom wall portion 21 of the chamber 2. The organic compound L in the source gas G supplied to the first space V1 adheres onto the film formation surface S1 of the substrate S held by the substrate holding part 3 in a state in which it is oriented along the electric field in this way. The organic compound L is anchored to the film formation surface S1 of the substrate S through chemical bonding between the first functional group of the organic compound L and the film formation surface S1 of the substrate S. That is to say, the organic compound L in the source gas G supplied to the first space V1 is anchored to the film formation surface S1 of the substrate S in a state in which it is erected with respect to the film formation surface S1 of the substrate S (namely, at an angle close to verticality as compared with a case where an electric field is not formed). Therefore, the organic compound L anchored to the film formation surface S1 of the substrate S is orderly arranged by the regulation from the film formation surface S1 of the substrate S, the interaction between the organic compounds L, and the like. This makes it possible for the SAM to have a larger thickness and a higher density than a case where no electric field is formed.

When the source gas G is supplied to the first space V1, an inert gas is supplied to the second space V2 by the gas purging part. Thus, the source gas G supplied to the first space V1 stays in the first space V1 and does not move to the second space V2. This prevents a SAM from being formed on the film non-formation surface S2 of the substrate S held by the substrate holding part 3.

The formation of a SAM on the film formation surface S1 of the substrate S is promoted by the substrate heating part 51 and the ultraviolet irradiation part 52. That is to say, when the source gas G is supplied into the chamber 2, the substrate S held by the substrate holding part 3 is heated by the substrate heating part 51. The temperature of the film formation surface S1 of the substrate S is increased by the heating, so that the formation of chemical bonds between the first functional group of the organic compound L and the film formation surface S1 of the substrate S is promoted. Thus, the formation of a SAM on the film formation surface S1 of the substrate S is promoted. Furthermore, ultraviolet rays are irradiated to the source gas G supplied to the first space V1 by the ultraviolet irradiation part 52. The first functional group of the organic compound L in the source gas G is activated by the ultraviolet rays so that the formation of chemical bonds between the first functional group of the organic compound L and the film formation surface S1 of the substrate S is promoted. Consequently, the formation of a SAM on the film formation surface S1 of the substrate S is promoted.

The substrate S having the SAM formed on the film formation surface S1 is unloaded from the film forming process unit 1 according to a procedure reverse to the procedure described above.

Various modifications may be made to the above embodiment. Hereinafter, modifications of the above embodiment will be described. Two or more of the following modifications may be combined.

### [Modification 1]

Modification 1 will be described below. In modification 1, the voltage applied to the frame portion 31 by the power source E is a positive DC voltage. In modification 1, as the positive DC voltage is applied to the frame portion 31 by the power source E, the frame portion 31 functions as an electrode having a more positive potential than the ground potential surface. That is to say, in modification 1, the frame portion 31 is positioned between the film formation surface S1 of the substrate S held by the substrate holding part 3 and the inner wall surface 210 of the bottom wall portion 21 of the chamber 2. The frame portion 31 functions as an electrode for forming an electric field in a direction extending from the film formation surface S1 of the substrate S held by the substrate holding part 3 toward the inner wall surface 210 of the bottom wall portion 22 of the chamber 2.

In modification 1, as an organic compound capable of forming a SAM, an organic compound L′ which has a main chain portion, a first functional group bonded to one end of the main chain portion and a second functional group bonded to the other end of the main chain portion and in which the first functional group is polarized to δ− and the second functional group is polarized to δ+, is used in place of the organic compound L.

In modification 1, in the first space V1 to which the source gas G is supplied, an electric field is formed in a direction extending from the film formation surface S1 of the substrate S held by the substrate holding part 3 toward the inner wall surface 210 of the bottom wall portion 21 of the chamber 2, as a negative DC voltage is applied to the frame portion 31 by the power source E. The electric field is formed throughout the time period from the start to the end of the supply of the source gas G to the first space V1. Therefore, the organic compound L′ in the source gas G supplied to the first space V1 is oriented along the electric field. That is to say, the first functional group polarized to δ− faces the side of the film formation surface S1 of the substrate S held by the substrate holding part 3, and the second functional group polarized to δ+ faces the side of the inner wall surface 210 of the bottom wall portion 21 of the chamber 2. The organic compound L′ in the source gas G supplied to the first space V1 adheres onto the film formation surface S1 of the substrate S held by the substrate holding part 3 in a state in which it is oriented along the electric field in this way. The organic compound L′ is anchored to the film formation surface S1 of the substrate S through the chemical bonding between the first functional group of the organic compound L′ and the film formation surface S1 of the substrate S. That is to say, the organic compound L′ in the source gas G supplied to the first space V1 is anchored to the film formation surface S1 of the substrate S in a state in which it is erected with respect to the film formation surface S1 of the substrate S (namely, at an angle close to verticality as compared with a case where an electric field is not formed). Therefore, the organic compound L′ anchored to the film formation surface S1 of the substrate S is orderly arranged by the regulation from the film formation surface S1 of the substrate S, the interaction between the organic compounds L′, and the like. This makes it possible to form a SAM having a larger thickness and a higher density than a case where no electric field is formed.

### [Modification 2]

Hereinafter, modification 2 will be described with reference to FIGS. 4 and 5. FIG. 4 is a sectional view of a substrate holding part 3′ according to modification 2, and FIG. 5 is a sectional view of a substrate S held by the substrate holding part 3′ shown in FIG. 4, which is viewed in a plan view from the side of the film formation surface S1 of the substrate S. The cross section of the substrate holding part 3′ in FIG. 4 corresponds to a cross section taken along line B-B in FIG. 5.

In modification 2, as shown in FIGS. 4 and 5, a mesh portion 33 is formed in the opening portion 30 of the frame portion 31 of the substrate holding part 3′. Other points are the same as those of the above-described embodiment. As shown in FIGS. 4 and 5, the mesh portion 33 has two or more opening portions 330 (twelve opening portions 330 in modification 2). The number of the opening portions 330 of the mesh portion 33 is not particularly limited as long as it is two or more, and may be appropriately changed. As shown in FIG. 5, the plan-view shape of each of the opening portions 330 of the mesh portion 33 is a rectangular shape. However, the plan-view shape of each of the opening portions 330 may be appropriately changed to other shapes (e.g., a circular shape or the like). The size of each of the opening portions 330 of the mesh portion 33 is, for example, 100 mm×50 mm.

The mesh portion 33 is formed of an electric conductor. The mesh portion 33 is electrically connected to the frame portion 31 and is electrically insulated from the ground potential surface of the chamber 2. As a negative DC voltage is applied to the frame portion 31 by the power source E, the negative DC voltage is also applied to the mesh portion 33. The electric conductor constituting the mesh portion 33 is, for example, a metallic material composed of a transition metal such as copper, nickel, titanium or the like, an alloy thereof, or a high-melting-point metal such as stainless steel, molybdenum, tungsten or the like. The mesh portion 33 may be a member separated from the frame portion 31 or may be integrally formed with the frame portion 31.

As the negative DC voltage is applied to the frame portion 31 and the mesh portion 33 by the power source E, the frame portion 31 and the mesh portion 33 function as electrodes having a more negative potential than the ground potential surface. That is to say, the frame portion 31 and the mesh portion 33 are positioned between the film formation surface S1 of the substrate S held by the substrate holding part 3 and the inner wall surface 210 of the bottom wall portion 21 of the chamber 2. The frame portion 31 and the mesh portion 33 function as electrodes for forming an electric field in a direction extending from the inner wall surface 210 of the bottom wall portion 21 of the chamber 2 toward the film formation surface S1 of the substrate S held by the substrate holding part 3.

Modification 2 is suitable for a case where the size of the frame portion 31 is large (namely a case where the size of the substrate S held by the substrate holding part 3 is large). In the case where the size of the frame portion 31 is large, the electric field formed by the frame portion 31 becomes weak in the central portion of the frame portion 31. On the other hand, in modification 2, the mesh portion 33 is formed in the opening portion 30 of the frame portion 31, and the frame portion 31 and the mesh portion 33 function as electrodes. Therefore, the electric field does not become weak even in the central portion of the frame portion 31.

### [Modification 3]

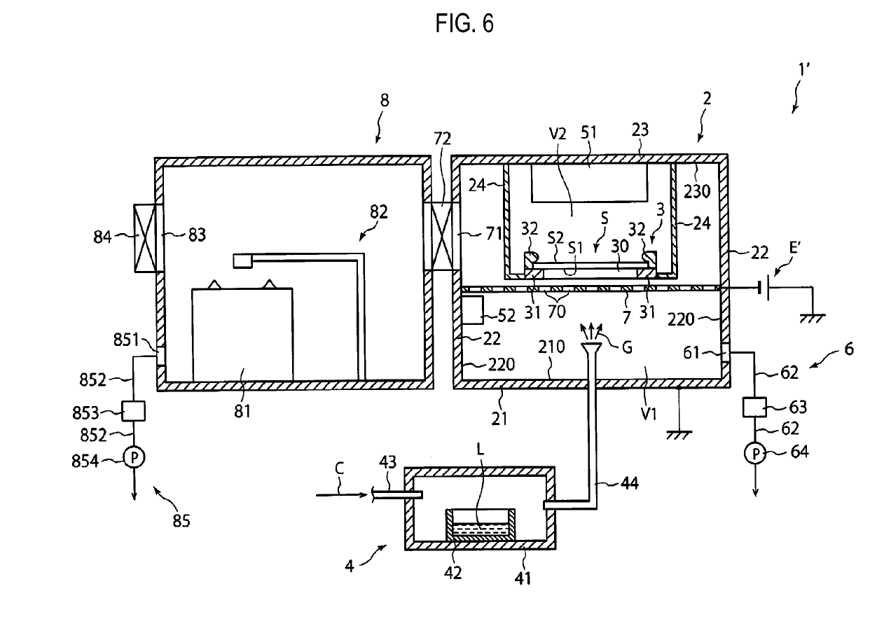

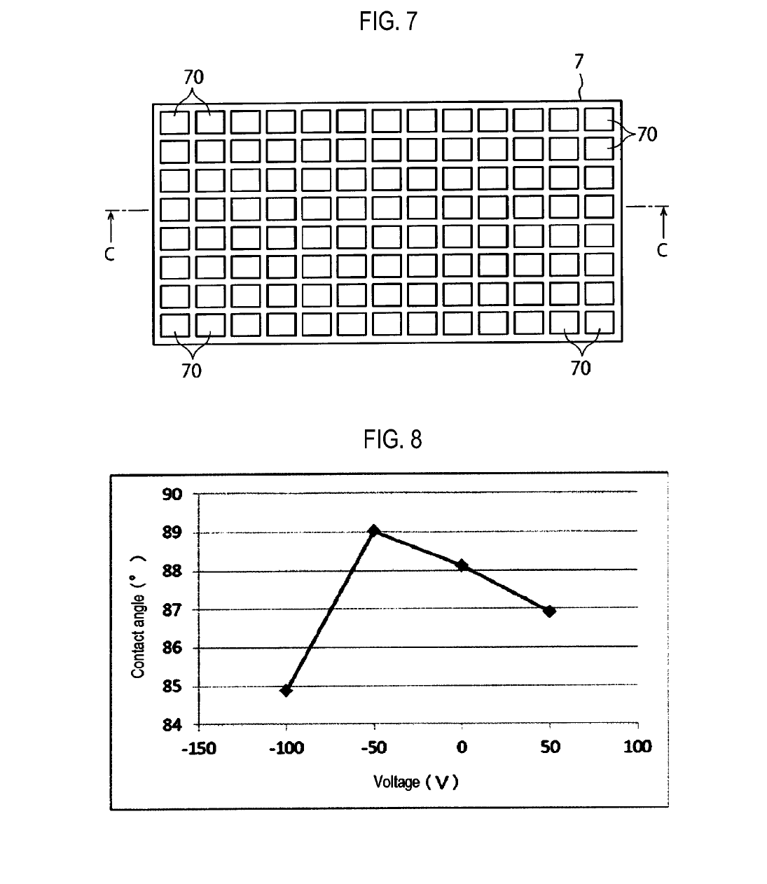

Modification 3 will be described below with reference to FIGS. 6 and 7. FIG. 6 is a partial sectional view showing a configuration of a film forming process unit 1′ according to modification 3, and FIG. 7 is a plan view of an electrode 7 included in the film forming process unit 1′ shown in FIG. 6, which is viewed in a plan view from the side of the bottom wall portion 21 of the chamber 2. The cross section of the electrode 7 in FIG. 6 corresponds to a cross section taken along line C-C in FIG. 7.

In modification 3, as shown in FIG. 6, a mesh electrode 7 positioned between the substrate holding part 3 and the inner wall surface 210 of the bottom wall portion 21 of the chamber 2 is installed inside the chamber 2 of the film forming process unit F. That is to say, in modification 3, the electrode 7 is installed as a member different from the electrode (the frame portion 31) of the substrate holding part 3. As shown in FIG. 6 and FIG. 7, the electrode 7 has two or more opening portions 70 (104 opening portions 70 in modification 2). The number of the opening portions 70 of the electrode 7 is not particularly limited as long as it is two or more, and may be appropriately changed. As shown in FIG. 7, the plan-view shape of each of the opening portions 70 of the electrode 7 is a rectangular shape. However, the plan-view shape of each of the opening portions 70 may be appropriately changed to other shapes (e.g., a circular shape or the like). The size of each of the opening portions 70 of the electrode 7 is, for example, 50 mm×100 mm.

The electrode 7 is installed in the vicinity of the film formation surface S1 of the substrate S held by the substrate holding part 3. The distance between the film formation surface S1 of the substrate S held by the substrate holding part 3 and the electrode 7 is, for example, 50 to 1,000 mm. The electrode 7 is formed of an electric conductor and is electrically insulated from the ground potential surface of the chamber 2. The electric conductor constituting the electrode 7 is a metallic material composed of a transition metal such as copper, nickel, titanium or the like, an alloy thereof, or a high-melting-point metal such as stainless steel, molybdenum, tungsten or the like. A power source E for applying a negative DC voltage to the electrode 7 is electrically connected to the electrode 7. The power source E′ electrically connected to the electrode 7 may be an internal power source included in the film formation apparatus 100 or an external power source. When the external power supply is electrically connected to the electrode 7, the film formation apparatus 100 may have an external power source connection terminal electrically connected to the electrode 7 and configured to connect the external power source to the electrode 7.

In modification 3, as a negative DC voltage is applied to the electrode 7 by the power source E′, the electrode 7 functions as an electrode having a more negative potential than the ground potential surface. That is to say, the electrode 7 is positioned between the film formation surface S1 of the substrate S held by the substrate holding part 3 and the inner wall surface 210 of the bottom wall portion 21 of the chamber 2. The electrode 7 functions as an electrode for forming an electric field in a direction extending from the inner wall surface 210 of the bottom wall portion 21 of the chamber 2 toward the film formation surface S1 of the substrate S accommodated in the chamber 2. In modification 3, the frame portion 31 is not electrically connected to the power source E and does not function as an electrode.

In modification 3, the source gas G is supplied between the electrode 7 and the inner wall surface 21 of the bottom wall portion 21 of the chamber 2. The source gas G passes through the opening portions 70 of the electrode 7 and reaches the film formation surface S1 of the substrate S held by the substrate holding part 3. As a negative DC voltage is applied to the electrode 7 by the power source E′, an electric field is formed between the electrode 7 and the inner wall surface 21 of the bottom wall portion 21 of the chamber 2 in a direction extending from the inner wall surface 210 of the bottom wall portion 21 of the chamber 2 toward the film formation surface S1 of the substrate S held by the substrate holding part 3. Therefore, the organic compound L in the supplied source gas G is oriented along the electric field. That is to say, the first functional group polarized to δ+ faces the side of the film formation surface S1 of the substrate S held by the substrate holding part 3, and the second functional group polarized to δ− faces the side of the inner wall surface 210 of the bottom wall portion 21 of the chamber 221. The organic compound L in the supplied source gas G adheres onto the film formation surface S1 of the substrate S held by the substrate holding part 3 in a state in which the organic compound L is oriented along the electric field in this way. The organic compound L is anchored to the film formation surface S1 of the substrate S through chemical bonding between the first functional group of the organic compound L and the film formation surface S1 of the substrate S. That is to say, the organic compound L in the supplied source gas G is anchored to the film formation surface S1 of the substrate S in a state in which it is erected with respect to the film formation surface S1 of the substrate S (namely, at an angle close to verticality as compared with a case where an electric field is not formed). Therefore, the organic compound L anchored to the film formation surface S1 of the substrate S is orderly arranged by the regulation from the film formation surface S1 of the substrate S, the interaction between the organic compounds L, and the like. This makes it possible to form a SAM having a larger thickness and a higher density than a case where no electric field is formed.

In modification 3, the frame portion 31 may be electrically connected to the power source E that applies a negative DC voltage to the frame portion 31. In this case, the absolute value of the negative DC voltage applied to the frame portion 31 may be larger than the absolute value of the negative DC voltage applied to the electrode 7. Thus, an electric field can be formed between the frame portion 31 and the electrode 7 in a direction extending from the inner wall surface 210 of the bottom wall portion 21 of the chamber 2 toward the film formation surface S1 of the substrate S accommodated in the chamber 2.

### [Modification 4]

In Modification 4, the substrate S is held by the substrate holding part 3 so that the film formation surface S1 of the substrate S faces upward (toward the side of the inner wall surface 230 of the upper wall portion 23 of the chamber 2) and the film non-formation surface S2 of the substrate S faces downward (toward the inner wall surface 210 of the bottom wall portion 21 of the chamber 2). In modification 4, the frame portion 31 supports the peripheral edge portion of the film non-formation surface S2 of the substrate S. In modification 4, the film non-formation surface S2 of the substrate S is exposed through the opening portion 30 of the frame portion 31 toward the inner wall surface 210 of the bottom wall portion 21 of the chamber 2. However, such exposure is not particularly necessary. Accordingly, in modification 4, the opening portion 30 of the frame portion 31 may be omitted. That is to say, a flat plate portion may be employed instead of the frame portion 31.

In modification 4, the inner wall surface 230 of the upper wall portion 23 among the inner wall surfaces of the chamber 2 becomes the facing inner wall surface that faces the film formation surface S1 of the substrate S held by the substrate holding part 3. In modification 4, among the inner wall surfaces of the chamber 2, at least the facing inner wall surface facing the film formation surface S1 of the substrate S held by the substrate holding part 3, namely the inner wall surface 230 of the upper wall portion 23 may be a ground potential surface. The inner wall surface 210 of the bottom wall portion 21 and the inner wall surface 220 of the peripheral wall portion 22 may not be ground potential surfaces.

In modification 4, the source gas G is discharged toward the film formation surface S1 of the substrate S from the tip of the source gas supply pipe 44 extending into the chamber 2 through the upper wall portion 23 of the chamber 2. That is to say, the source gas G is supplied in a direction extending from the inner wall surface 230 of the upper wall portion 23 of the chamber 2 toward the film formation surface S1 of the substrate S held by the substrate holding part 3.

In modification 4, the chuck portion 32 of the substrate holding part 3 is formed of an electric conductor and is electrically insulated from the ground potential surface of the chamber 2. In modification 4, a power source E for applying a negative DC voltage to the chuck portion 32 is electrically connected to the chuck portion 32. The power source E electrically connected to the chuck portion 32 may be an internal power source included in the film formation apparatus 100 or may be an external power source. In the case where the external power supply is electrically connected to the chuck portion 32, the film formation apparatus 100 may include an external power source connection terminal electrically connected to the chuck part 32 and configured to connect the external power supply to the chuck portion 32.

In modification 4, as the negative DC voltage is applied to the chuck portion 32 by the power source E, the chuck portion 32 functions as an electrode having a more negative potential than the ground potential surface. That is to say, the chuck portion 32 is positioned between the film formation surface S1 of the substrate S held by the substrate holding part 3 and the inner wall surface 230 of the upper wall portion 23 of the chamber 2. The chuck portion 32 functions as an electrode for forming an electric field in a direction extending from the inner wall surface 230 of the upper wall portion 23 of the chamber 2 toward the film formation surface S1 of the substrate S held by the substrate holding part 3. Since the substrate S is not interposed between the chuck portion 32 and the inner wall surface 230 of the upper wall portion 23 of the chamber 2, the electric field generated by the application of the voltage to the chuck portion 32 is hardly affected by the dielectric constant of the substrate S. Thus, regardless of the material of the substrate S, an electric field having a desired intensity can be formed between the film formation surface S1 of the substrate S held by the substrate holding part 3 and the inner wall surface 230 of the upper wall portion 23 of the chamber 2.

### Example

A SAM was formed on the film formation surface S1 of the substrate S held by the substrate holding part 3, by causing the film formation apparatus 100 shown in FIGS. 1 to 3 to perform: a process (a) of accommodating a substrate S in the chamber 2 having a ground potential surface as an inner wall surface so that at least a portion of the ground potential surface (the inner wall surface 210 of the bottom wall portion 21 of the chamber 2 in the present embodiment) becomes a facing inner wall surface facing the film formation surface S1 of the substrate S; and a process (b) of supplying a SAM source gas G into the chamber 2.

A substrate made of SiO₂ (glass) was used as the substrate S, and the Si (111) surface of the substrate was defined as the film formation surface S1. Before the process (a), the film formation surface S1 of the substrate S was subjected to a plasma treatment to introduce Si—H bonds to the film formation surface S1 of the substrate S. As an organic compound L capable of forming a SAM, CH₂═CH—CH₂—O—CH₂—CF₂—CF₃ was used. In CH₂═CH—CH₂—O—CH₂—CF₂—CF₃, —CH═CH₂ as a first functional group is polarized to δ+, —CF₂—CF₃ as a second functional group is polarized to δ−. The internal atmospheric pressure of the chamber 2 was reduced to 10⁻⁴ to 10⁻⁶ Pa. The ultraviolet irradiation part 52 was used as a film formation promotion treatment part for performing a SAM formation promotion treatment on the film formation surface S1 of the substrate S held by the substrate holding part 3. However, the substrate heating part 51 was not used. Therefore, the substrate S held by the substrate holding part 3 is maintained at room temperature (20 to 30 degrees C.) inside the chamber 2 through the processes (a) and (b). The flow rate of the carrier gas C introduced into the gas generation container 41 from the carrier gas introduction pipe 43 was adjusted to 50 sccm. The term “sccm” represents cc (cm³) per minute in a standard state (0 degrees C./1 atm). The distance between the tip of the source gas supply pipe 44 and the film formation surface S1 of the substrate S held by the substrate holding part 3 was adjusted to 200 mm A DC voltage of +50V, 0V, −50V or −100V was applied to the frame portion 31.

A contact angle of the SAM formed on the film formation surface S1 of the substrate S with respect to water was measured by a droplet dropping method using pure water. For the measurement of the contact angle, a wettability evaluation device LSE-A series manufactured by Nick Corporation was used. The device used is the same as LSE-A110 except that a stage is a special order item. The measurement method of the contact angle is the same as LSE-A110.

FIG. 8 shows the relationship between a DC voltage applied to the frame portion 31 and a contact angle of the SAM formed on the film formation surface S1 of the substrate S with respect to water. As shown in FIG. 8, the contact angle of the SAM with respect to water when a DC voltage of −50 V is applied to the frame portion 31 was larger than when no voltage is applied to the frame portion 31 (voltage of 0V) and when a DC voltage of +50 V is applied to the frame portion 31. As the contact angle grows larger, the water repellency of the SAM, namely the density of the SAM becomes higher. Therefore, the result shown in FIG. 8 indicates that when a DC voltage of −50 V is applied to the frame portion 31, a SAM is formed having a higher density than when no DC voltage is applied to the frame portion 31 (voltage of 0V) and when a DC voltage of +50 V is applied to the frame portion 31. When a DC voltage of −100 V is applied to the frame portion 31, the contact angle of the SAM with respect to water was smaller than when a DC voltage of −50 V is applied to the frame portion 31. Thus, an optimum value is considered to exist in the applied voltage value.

According to the present disclosure, it is possible to provide a film formation apparatus and a film formation method capable of forming a high-density self-assembled monomolecular film, and a storage medium storing a program for executing the film formation method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film formation apparatus for forming a self-assembled monomolecular film on a film formation surface of a substrate, comprising:
a chamber configured to accommodate the substrate, the chamber including a facing inner wall surface facing the film formation surface of the substrate accommodated in the chamber, the facing inner wall surface being a ground potential surface;
a source gas supply part configured to supply a source gas for the self-assembled monomolecular film into the chamber; and
an electrode positioned between the film formation surface of the substrate accommodated in the chamber and the facing inner wall surface of the chamber, and configured to form an electric field in a direction extending from the film formation surface of the substrate accommodated in the chamber toward the facing inner wall surface of the chamber or in a direction extending from the facing inner wall surface of the chamber toward the film formation surface of the substrate accommodated in the chamber.

2. The apparatus of claim 1, wherein the source gas supply part is configured to supply the source gas in the direction extending from the facing inner wall surface of the chamber toward the film formation surface of the substrate accommodated in the chamber.

3. The apparatus of claim 1, further comprising:
a substrate holding part configured to hold the substrate inside the chamber and to orient the film formation surface of the substrate toward the facing inner wall surface of the chamber,
wherein the substrate holding part includes the electrode.

4. The apparatus of claim 3, wherein the substrate holding part includes a frame portion having an opening portion through which the film formation surface of the substrate is exposed toward the facing inner wall surface of the chamber, and
the frame portion functions as the electrode.

5. The apparatus of claim 4, wherein the substrate holding part includes a mesh portion formed in the opening portion of the frame portion, and
the frame portion and the mesh portion function as the electrode.

6. The apparatus of claim 1, further comprising:
a substrate holding part configured to hold the substrate inside the chamber and to orient the film formation surface of the substrate toward the facing inner wall surface of the chamber,
wherein the electrode is positioned between the substrate holding part and the facing inner wall surface of the chamber.

7. The apparatus of claim 6, wherein the electrode has a mesh shape.

8. The apparatus of claim 1, further comprising:
a film formation promotion treatment part configured to perform a formation promotion treatment of the self-assembled monomolecular film on the film formation surface of the substrate accommodated in the chamber.

9. A film formation method for forming a self-assembled monomolecular film on a film formation surface of a substrate, comprising:
accommodating the substrate in a chamber having a ground potential surface as an inner wall surface so that at least a portion of the ground potential surface becomes a facing inner wall surface facing the film formation surface of the substrate; and
supplying a source gas for the self-assembled monomolecular film into the chamber,
wherein in the supplying a source gas, an electric field is formed by an electrode positioned between the film formation surface of the substrate accommodated in the chamber and the facing inner wall surface of the chamber, in a direction extending from the film formation surface of the substrate accommodated in the chamber toward the facing inner wall surface of the chamber or in a direction extending from the facing inner wall surface of the chamber toward the film formation surface of the substrate accommodated in the chamber.

10. The method of claim 9, wherein in the supplying a source gas, the source gas is supplied in the direction extending from the facing inner wall surface of the chamber toward the film formation surface of the substrate accommodated in the chamber.

11. The method of claim 9, wherein the accommodating the substrate includes holding the substrate inside the chamber by a substrate holding part installed inside the chamber so that at least a portion of the ground potential surface becomes the facing inner wall surface facing the film formation surface of the substrate, and
the substrate holding part includes the electrode.

12. The method of claim 11, wherein the substrate holding part includes a frame portion having an opening portion through which the film formation surface of the substrate is exposed toward the facing inner wall surface of the chamber, and
the frame portion functions as the electrode.

13. The method of claim 12, wherein the substrate holding part includes a mesh portion formed in the opening portion of the frame portion, and
the frame portion and the mesh portion function as the electrode.

14. The method of claim 9, wherein the accommodating the substrate includes holding the substrate inside the chamber by a substrate holding part installed inside the chamber so that at least a portion of the ground potential surface becomes the facing inner wall surface facing the film formation surface of the substrate, and
the electrode is positioned between the substrate holding part and the facing inner wall surface of the chamber.

15. The method of claim 14, wherein the electrode has a mesh shape.

16. The method of claim 9, wherein the supplying a source gas includes performing a formation promotion treatment of the self-assembled monomolecular film on the film formation surface of the substrate accommodated in the chamber.

17. A non-transitory computer-readable storage medium storing a program that, when executed by a computer for controlling an operation of a film formation apparatus, causes the computer to control the film formation apparatus so as to perform the film formation method of claim 9.
